(19) United States
(12) Patent Application Publication
(10) Pub. No.: US 2022/0285170 A1
(43) Pub. Date: Sep. 8, 2022

(54) METHOD OF MANUFACTURING SEMICONDUCTOR DEVICE, METHOD OF MANUFACTURING STACKED WIRING STRUCTURE, AND ION BEAM IRRADIATION APPARATUS

(71) Applicant: Kioxia Corporation, Tokyo (JP)

(72) Inventors: Junichi HASHIMOTO, Yokkaichi (JP); Toshiyuki SASAKI, Yokkaichi (JP)

(73) Assignee: Kioxia Corporation, Tokyo (JP)

(21) Appl. No.: 17/346,921

(22) Filed: Jun. 14, 2021

(30) Foreign Application Priority Data
Mar. 5, 2021 (JP) 2021-035803

(51) Int. Cl. H01L 21/425; H01J 37/08; H01J 37/32

(52) U.S. Cl. CPC H01L 21/425; H01J 37/08; H01J 37/32412; H01J 2237/3348; H01J 2237/0815

(57) ABSTRACT

A method of manufacturing a semiconductor device includes: preparing a stacked body in which a first layer, a second layer, a third layer, and a fourth layer are stacked in this order on a semiconductor substrate in a first direction, the stacked body including a first region and a second region different from the first region; etching the fourth layer in the first region and the second region to expose the third layer by irradiating the first region and the second region with an ion beam, and etching the third layer and the second layer in the second region to expose the first layer by irradiating the second regions with an ion beam in a state where the third layer is exposed in the first region.

### CROSS REFERENCE TO RELATED APPLICATION(S)

This application is based upon and claims the benefit of priority from the prior Japanese Patent Application No. 2021-035803 filed on Mar. 5, 2021, the entire contents of which are incorporated herein by reference.

### FIELD

Embodiments described herein relate generally to a method of manufacturing a semiconductor device, a method of manufacturing a stacked wiring structure, and an ion beam irradiation apparatus.

### BACKGROUND

The semiconductor package using a NAND flash memory as a semiconductor device is known. In order to increase the capacity of such NAND flash memory, a three-dimensional NAND flash memory having a configuration that a large number of memory cells are stacked has been put into practical use. A plurality of conductive layers connected to each memory cell is stacked on a substrate and connected to a driving circuit or the like.

### BRIEF DESCRIPTION OF THE DRAWINGS

FIG. 1 is a perspective view showing an entire configuration of a semiconductor device according to an embodiment;

FIG. 2 is a perspective view showing a configuration of a memory cells region MCR and a drawn region HUR of a semiconductor device according to an embodiment;

FIG. 3A is a top view showing a configuration of a stacked wiring structure of a semiconductor device according to an embodiment;

FIG. 3B is a cross-sectional view showing a configuration of a stacked wiring structure of a semiconductor device according to an embodiment;

FIG. 4A is a top view showing a method of manufacturing a stacked wiring structure according to an embodiment;

FIG. 4B is a cross-sectional view showing a method of manufacturing a stacked wiring structure according to an embodiment;

FIG. 5A is a top view showing a method of manufacturing a stacked wiring structure according to an embodiment;

FIG. 5B is a cross-sectional view showing a method of manufacturing a stacked wiring structure according to an embodiment;

FIG. 6A is a top view showing a method of manufacturing a stacked wiring structure according to an embodiment;

FIG. 6B is a cross-sectional view showing a method of manufacturing a stacked wiring structure according to an embodiment;

FIG. 7A is a top view showing a method of manufacturing a stacked wiring structure according to an embodiment;

FIG. 7B is a cross-sectional view showing a method of manufacturing a stacked wiring structure according to an embodiment;

FIG. 8A is a top view showing a method of manufacturing a stacked wiring structure according to an embodiment;

FIG. 8B is a cross-sectional view showing a method of manufacturing a stacked wiring structure according to an embodiment;

FIG. 9A is a top view showing a method of manufacturing a stacked wiring structure according to an embodiment;

FIG. 9B is a cross-sectional view showing a method of manufacturing a stacked wiring structure according to an embodiment;

FIG. 10A is a top view showing a method of manufacturing a stacked wiring structure according to an embodiment;

FIG. 10B is a cross-sectional view showing a method of manufacturing a stacked wiring structure according to an embodiment;

FIG. 11 is a schematic diagram showing a configuration of an ion beam irradiation apparatus according to an embodiment;

FIG. 12A is a top view showing a method of manufacturing a stacked wiring structure according to an embodiment;

FIG. 12B is a cross-sectional view showing a method of manufacturing a stacked wiring structure according to an embodiment;

FIG. 13A is a top view showing a method of manufacturing a stacked wiring structure according to an embodiment;

FIG. 13B is a cross-sectional view showing a method of manufacturing a stacked wiring structure according to an embodiment;

FIG. 14A is a top view showing a configuration of a stacked wiring structure of a semiconductor device according to an embodiment;

FIG. 14B is a cross-sectional view showing a configuration of a stacked wiring structure of a semiconductor device according to an embodiment;

FIG. 15A is a top view showing a method of manufacturing a stacked wiring structure according to an embodiment;

FIG. 15B is a cross-sectional view showing a method of manufacturing a stacked wiring structure according to an embodiment;

FIG. 16A is a top view showing a configuration of a stacked wiring structure of a semiconductor device according to an embodiment;

FIG. 16B is a cross-sectional view showing a configuration of a stacked wiring structure of a semiconductor device according to an embodiment;

FIG. 17A is a top view and a cross-sectional view showing a method of manufacturing a stacked wiring structure according to an embodiment;

FIG. 17B is a cross-sectional view showing a method of manufacturing a stacked wiring structure according to an embodiment;

FIG. 18 is a schematic diagram showing a configuration of an ion beam irradiation apparatus according to an embodiment; and

FIG. 19 is a schematic diagram showing a configuration of an ion beam irradiation apparatus according to a modified example.

### DETAILED DESCRIPTION

A method of manufacturing a semiconductor device according to the present embodiment includes: preparing a stacked body in which a first layer, a second layer, a third layer, and a fourth layer are stacked in this order on a semiconductor substrate in a first direction, the stacked body including a first region and a second region different from the first region; etching the fourth layer in the first region and the second region to expose the third layer by irradiating the first region and the second region with an ion beam, and etching the third layer and the second layer in the second region to expose the first layer by irradiating the second regions with an ion beam in a state where the third layer is exposed in the first region.

Hereinafter, a method of manufacturing a semiconductor device, a method of manufacturing a stacked wiring structure, and an ion beam irradiation apparatus according to the present embodiment will be described in detail by referring to the drawings. In the following description, components having substantially the same functions and configurations are denoted by the same reference symbols or with the same reference symbols followed by the addition of an alphabet and will be described in duplicate only when necessary. Each of the embodiments described below exemplifies a device and a method for embodying a technical idea of the present embodiment. The technical idea of the embodiment is not specified as materials, shapes, structures, arrangements, and the like of the parts described below. Various modifications may be made to the technical idea of the embodiment in addition to the scope of the claims.

For the sake of clarity of description, the drawings may be schematically represented with respect to widths, thicknesses, shapes, and the like of the respective portions compared with actual embodiments but are merely an example and do not limit the interpretation of the present invention. In this specification and each drawing, elements having the same functions as those described with reference to the preceding drawings are denoted by the same reference symbols, and a repetitive description thereof may be omitted.

A plurality of films formed by the same process has the same layer structure and is made of the same material. In this specification, even when a plurality of films has different functions or roles, the plurality of films formed by the same process in this way is treated as films existing in the same layer.

In the embodiments, the direction from a substrate to a memory cell is referred to as an upward direction. On the contrary, the direction from a memory cell to a substrate is referred to as a downward direction. As described above, for convenience of explanation, the phrase “upward” or “downward” is used for explanation, but, for example, a substrate and a memory cell may be arranged so that the vertical relationship is opposed to that shown in the drawings. In the following description, for example, the expression “a memory cell on a substrate” merely describes the vertical relationship between the substrate and the memory cell as described above, and other member may be arranged between the substrate and the memory cell.

The expressions “a includes A, B or C,” “α includes any of A, B and C,” “α includes one selected from a group consisting of A, B and C,” and the like do not exclude the case where α includes multiple combinations of A to C unless otherwise specified. Furthermore, these expressions do not exclude the case where α includes other elements.

The following embodiments may be combined with each other as long as there is no technical contradiction.

In the following embodiments, a memory cell array is described as an example of a semiconductor device, but the disclosed techniques can be applied to a semiconductor device other than a memory cell array (e.g., CPUs, display units, interposers, etc.).

### First Embodiment

### [Entire Configuration of Semiconductor Device]

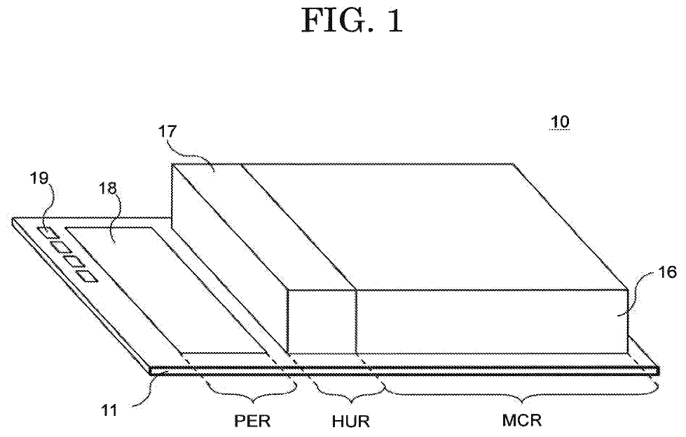

An entire configuration of a semiconductor device according to the present embodiment will be described with reference to FIG. 1. FIG. 1 is a perspective view showing an arrangement of each element of a semiconductor device 10 according to the present embodiment.

The semiconductor device 10 is a NAND flash memory device and includes memory cells arranged in three dimensions. Specifically, a source-side select gate transistor, a large number (e.g., 64) of memory cell transistors, and a drain-side select gate transistor are connected in series in a direction perpendicular to a surface of a semiconductor substrate 11 to constitute a memory string. A dummy cell transistor may be included at both ends of a large number of memory cell transistors connected in series, or between a part of a large number of memory cell transistors.

The semiconductor device 10 is formed on the semiconductor substrate 11. A memory cells region MCR and a drawn region HUR are partitioned on the semiconductor substrate 11. A memory cell array 16 including a plurality of memory cells stacked in three dimensions is formed in the memory cells region MCR. The memory cell array 16 includes a stacked body in which a plurality of conductive layers and a plurality of insulating layers are alternately stacked. This plurality of conductive layers functions as source-side select gate line, word lines, and drain-side select gate line connected to each transistor in the memory string. The plurality of conductive layers and the plurality of insulating layers extend to the drawn region HUR to form a stacked wiring structure 17. Bit lines (not shown) are provided on the memory cell array 16 and connected to a peripheral circuit 18. Wirings (not shown) are provided on the stacked wiring structure 17 and connected to the peripheral circuit 18.

A peripheral circuit region PER is further partitioned on the semiconductor substrate 11. The peripheral circuit 18 is formed in the peripheral circuit region PER. The peripheral circuit 18 includes a large number of CMOS transistors. The peripheral circuit 18 includes column-based circuit including a driving circuit configured to drive each word line connected to the memory cell, a decoder circuit configured to select each word line, a sense amplifier configured to sense a bit line potential at the time of reading, and a bit line potential control circuit configured to supply a voltage to the bit line at the time of writing. In FIG. 1, the wirings of the peripheral circuit region PER is omitted. The semiconductor substrate 11 has a pad row 19 for exchanging signals to the outside of the chip and receiving a power supply.

### [Configuration of Memory Cells Region MCR and Drawn Region HUR]

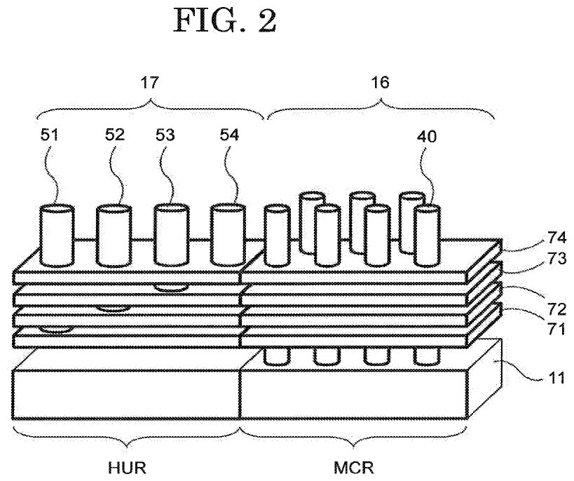

FIG. 2 is a perspective view showing a configuration of the memory cells region MCR and the drawn region HUR of the semiconductor device according to the present embodiment. In order to prevent the figure from being confused, a member having conductivity is shown, and hatchings in the drawing are omitted. The portion where the member is not shown in FIG. 2 is insulated using an insulating material such as silicon dioxide.

In the memory cells region MCR, the memory cell array 16 is formed on the semiconductor substrate 11 containing the silicon single crystal. The memory cell array 16 includes an insulating layer, a conductive layer 71, an insulating layer, a conductive layer 72, an insulating layer, a conductive layer 73, an insulating layer, and a conductive layer 74 that extend parallel to the surface of the semiconductor substrate 11. The memory cell array 16 includes a stacked body in which the plurality of insulating layers and the plurality of conductive layers are alternately stacked. Although only four conductive layers are shown in the figure, a larger number of conductive layers such as 33 layers, 65 layers are stacked. These conductive layers correspond to the source-side select gate line, the word lines, or the drain-side select gate line connected to the transistors.

Memory pillars 40 that penetrate the plurality of insulating layers and the plurality of conductive layers are formed in the memory cells region MCR. The memory pillar 40 has a cylindrical shape, and from the outer peripheral side toward the center side, a block insulating film containing a silicon dioxide film, a charge storage film containing a silicon nitride film, a tunnel insulating film containing a silicon dioxide film, a semiconductor channel containing an amorphous or polycrystalline silicon film, and a silicon dioxide film are stacked. The portion surrounded by the conductive layers 71, 72, 73, and 74 (corresponding to the select gate lines or word lines) functions as a part of a non-volatile memory cell that traps the carrier in the silicon nitride film.

In the drawn region HUR, the stacked wiring structure 17 is formed on the semiconductor substrate 11 containing the silicon single crystal. The plurality of insulating layers and the plurality of conductive layers extending from the memory cells region MCR are also formed in the drawn region HUR. The stacked wiring structure 17 includes the insulating layer, the conductive layer 71, the insulating layer, the conductive layer 72, the insulating layer, the conductive layer 73, the insulating layer, the semiconductor substrate 74, and the insulating layer that extend parallel to the surface of the semiconductor substrate 11. The stacked wiring structure 17 includes the stacked body in which the plurality of insulating layers and the plurality of conductive layers are alternately stacked. Although only four conductive layers are shown in the figure, it is as described above that a larger number of conductive layers such as 33 layers, 65 layers are stacked. These conductive layers correspond to the wirings drawn from the word lines, the source-side select gate line, or the drain-side select gate line in the drawn region HUR.

In the drawn region HUR, the conductive layers 71, 72, 73, and 74 (corresponding to the wirings drawn from the select gate lines or word lines) are connected to the corresponding contact plugs 51, 52, 53, and 54 (when not distinguishing the contact plugs 51, 52, 53, and 54, referred to as the contact plugs 50). Each contact plug 50 is drawn over the stacked wiring structure 17 via a contact hole penetrating the plurality of insulating layers and the plurality of conductive layers.

The contact plug 50 has a larger diameter and a larger cross-sectional area than the memory pillar 40. The contact plug 50 has a smaller arrangement density than the memory pillar 40. In other words, the contact plug 50 does not need to be arranged at a high density in a small region as the memory pillar 40.

### [Configuration of Stacked Wiring Structure]

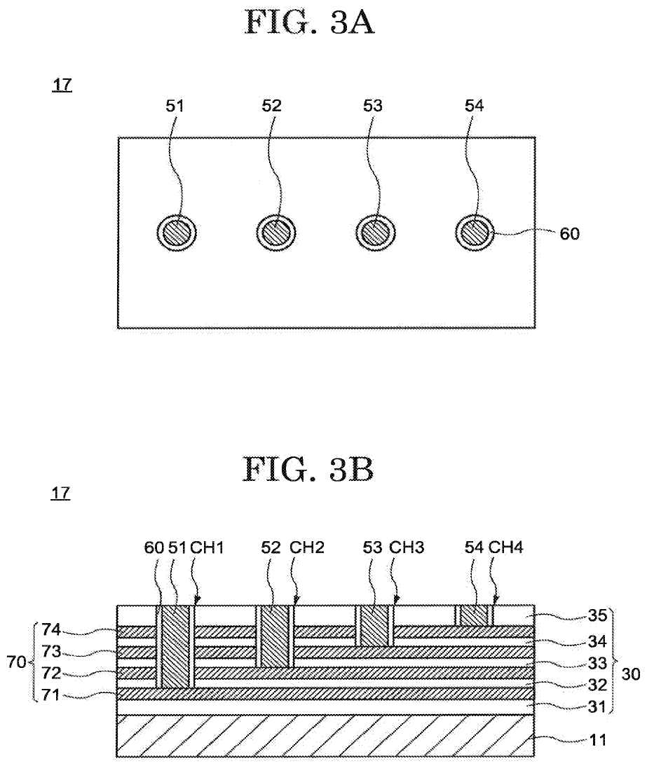

FIG. 3A is a top view showing a configuration of the stacked wiring structure 17. FIG. 3B is a cross-sectional view showing a configuration of the stacked wiring structure 17. The stacked wiring structure 17 has the plurality of conductive layers 71, 72, 73, and 74 stacked on the semiconductor substrate 11 (when not distinguishing the plurality of conductive layers 71, 72, 73, and 74, referred to as the conductive layers 70). The plurality of conductive layers 71, 72, 73, and 74, and a plurality of insulating layers 31, 32, 33, 34, and 35 (when not distinguishing the plurality of insulating layers 31, 32, 33, 34, and 35, referred to as the insulating layers 30), are periodically stacked in a direction perpendicular to the main surface of the semiconductor substrate 11 (stacking direction). Each conductive layer 70 is a single layer. That is, when observing the cross-sectional shape for one conductive layer 70, a single material may be continuous in a film thickness direction (Z-direction) of the conductive layer 70. Also, there is no need to be an interface within one conductive layer 70. The conductive layer 70 may be tungsten, for example.

The insulating layer 30 is formed between the conductive layers 70 adjacent in the stacking direction. The insulating layer 31 is also formed between the semiconductor substrate 11 and the lowermost conductive layer 71. The conductive layers 70 adjacent to each other in the stacking direction are insulated from each other, and the material of the insulating layer 30 may be silicon oxide such as silicon dioxide (SiO₂), TEOS (Tetra Ethyl Ortho Silicate). The insulating layer 30 is deposited, for example, using a CVD (Chemical Vapor Deposition) apparatus.

Contact holes CH1, CH2, CH3, and CH4 (when not distinguishing the contact holes CH1, CH2, CH3, and CH4, referred to as the contact holes CH) are formed up to the corresponding conductive layers 71, 72, 73, and 74 by penetrating the plurality of conductive layers 70 and the plurality of insulating layers 30, which are the upper layer and stacked with each other. The contact hole CH1 is formed in common in the conductive layers 72, 73, 74, and the insulating layers 32, 33, 34, 35, with the conductive layer 71 as the bottom. The contact hole CH2 is formed in common in the conductive layers 73, 74, and the insulating layers 33, 34, 35, with the conductive layer 72 as the bottom. The contact hole CH3 is formed in common in the conductive layer 74, and the insulating layers 34, 35, with the conductive layer 73 as the bottom. The contact hole CH4 is formed in the insulating layer 35 with the conductive layer 74 as the bottom. That is, the depth of each of the contact holes CH1, CH2, CH3, and CH4 from the upper surface of the stacked wiring structure 17 is different. In the present embodiment, the contact hole CH has substantially the same diameter at the top surrounded by the insulating layer 35 and at the bottom connected to the corresponding conductive layer. However, without being limited thereto, the contact hole CH may have different diameters at the top and bottom or may have a larger diameter at the intermediate portion between the top and bottom than at the top or bottom.

The contact plug 50 is formed in the contact hole CH. The contact plug 51 is connected to the conductive layer 71 at the bottom of the contact hole CH1. The contact plug 52 is connected to the corresponding conductive layer 72 at the bottom of the contact hole CH2.

The contact plug 53 is connected to the conductive layer 73 at the bottom of the contact hole CH3. The contact plug 54 is connected to the corresponding conductive layer 74 at the bottom of the contact hole CH4. That is, the length of the contact plugs 51, 52, 53, 54 from the upper surface of the stacked wiring structure 17 is different, respectively.

The contact plug 50 has a cylindrical shape, and the material of the contact plug 50 may be, for example, a metal such as tungsten.

The contact plug 50 is insulated from the upper conductive layer 70 penetrating by the contact hole CH. An insulating film 60 is formed in a cylindrical shape on the side surface of the contact hole CH. That is, the side surface of the contact plug 50 is covered with the insulating film 60. The material of the insulating film 60 may be, for example, silicon oxide such as silicon dioxide (SiO₂), TEOS.

### [Method of Manufacturing Stacked Wiring Structure]

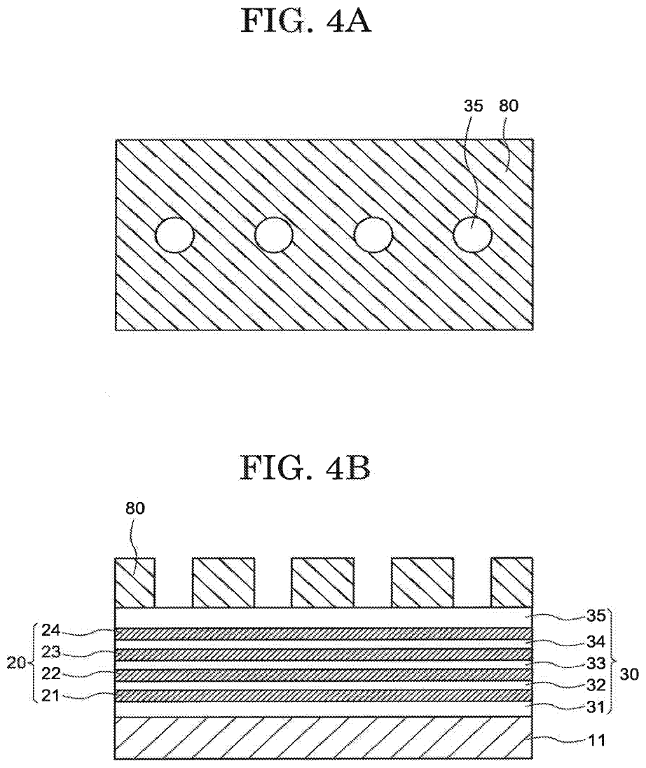

Referring to FIGS. 4A to 10B, a method of manufacturing the stacked wiring structure 17 according to the present embodiment will be described.

First, as shown in FIGS. 4A and 4B, the insulating layer 31 (TEOS film), a sacrificial layer 21 (SiN film), the insulating layer 32 (TEOS film), a sacrificial layer 22 (SiN film), the insulating layer 33 (TEOS film), a sacrificial layer 23 (SiN film), the insulating layer 34 (TEOS film), a sacrificial layer 24 (SiN film), and the insulating layer 35 (TEOS film) are sequentially formed on the semiconductor substrate 11 to form a stacked body. These insulating layers 31, 32, 33, 34, and 35 (TEOS films) and the sacrificial layers 21, 22, 23, and 24 (SiN films, when not distinguishing the sacrificial layers 21, 22, 23, and 24, referred to as the sacrificial layers 20) are deposited, for example, using the CVD device. The alternately stacked insulating layer 30 and the sacrificial layer 20 are formed in contact with each other. In the present embodiment, the material of the insulating layer 30 is exemplified by the TEOS film, but the material of the insulating layer 30 is not limited to this, and may be, for example, silicon dioxide (SiO₂). In the present embodiment, the material of the sacrifice layer 20 is exemplified by the silicon nitride film SiN, but the material of the sacrifice layer 20 is not limited to this, and may be, for example, silicon or a metal such as tungsten.

A mask 80 having a pattern of the contact hole CH is formed on the stacked body. The mask 80 is preferably a hard mask, and a material of the mask 80 may be, for example, carbon. The material of the mask 80 may include two or more materials of different compositions, in which case the mask 80 may have a stacked structure containing two or more layers containing materials having different compositions. The mask 80 is deposited, for example, using the CVD device. The pattern of the mask 80 is formed using a resist mask formed by performing photolithography to a resist. The pattern of the mask 80 has openings that expose the insulating layer 35 to the region where the contact hole CH is formed.

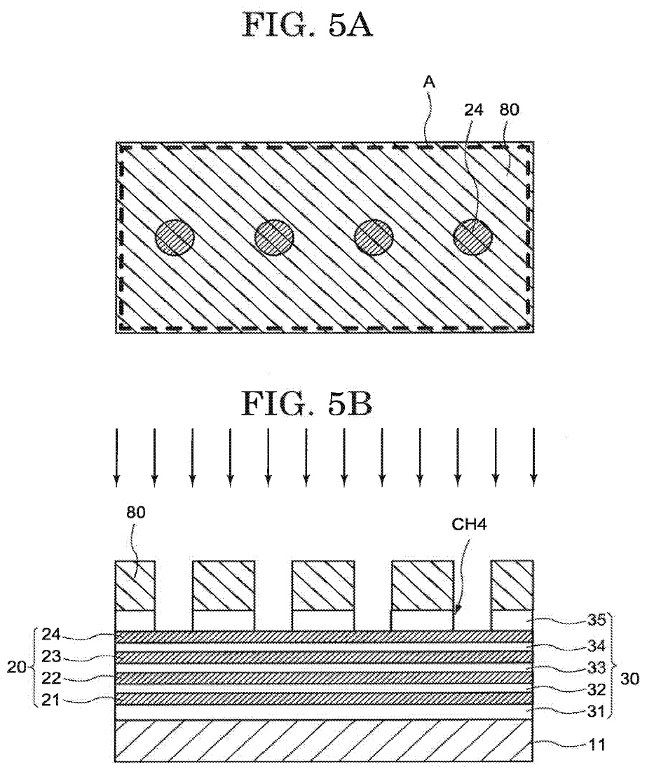

As shown in FIGS. 5A to 8B, the contact hole CH is formed by etching by irradiating a specific region with an ion beam through the mask 80 using an ion beam irradiation apparatus to be described later. First, as shown in FIG. 5A and FIG. 5B, by irradiating a region A (the first, second, third and fourth regions) containing all the regions where the contact holes CH1, CH2, CH3, and CH4 are formed with the ion beam, the insulating layer 35 of the stacked body exposed by the mask 80 in the region A is selectively etched. The region A may be the entire drawn region HUR or may be the smallest region including all the regions where the contact holes CH1, CH2, CH3, and CH4 are formed.

To selectively etch the insulating layer 35, the ion beam preferably contains ion species having a higher selectivity for the insulating layer 35 than the sacrificial layer 24. When the insulating layer 35 contains silicon oxide and the sacrificial layer 24 contains silicon nitride, silicon, or tungsten, the ion species is preferably CxFy+ion not containing H. CxFy+ion may be, for example, C₃F₅+ion, or C₄F₆+ion. By irradiating the ion beam containing such ion species, the sacrificial layer 24 functions as an etching stopper, and the insulating layer 35 can be selectively etched. Selectively etching of the insulating layer 35 of the stacked body exposes the sacrificial layer 24 to form the contact hole CH4.

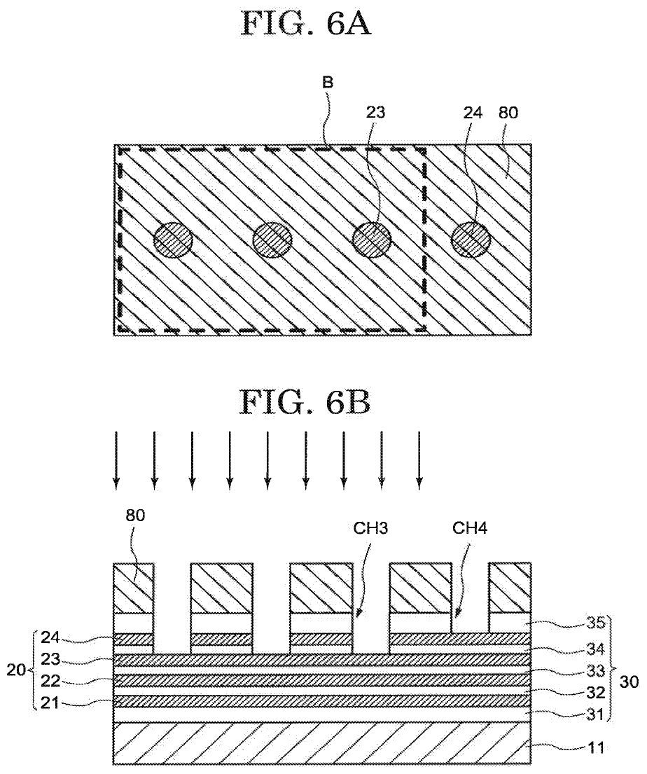

As shown in FIGS. 6A and 6B, by irradiating a region B (second, third and fourth regions) containing all the regions where the contact holes CH1, CH2, and CH3 are formed with the ion beam, the sacrificial layer 24 of the stacked body exposed by the mask 80 in the region B is selectively etched. The region B is a part of the region A. The region B does not contain the region where the contact hole CH4 is formed and may be the smallest region containing all the regions where the contact holes CH1, CH2, and CH3 are formed. To selectively etch the sacrificial layer 24, the ion beam preferably contains ion species having a higher selectivity for the sacrificial layer 24 than the insulating layer 34. When the insulating layer 34 contains silicon oxide and the sacrificial layer 24 contains silicon nitride or silicon, the ion species is preferably CxHyFz+ion containing H. CxHyFz+ion may be, for example, CHF₂+ion or CH₂F+ion. When the insulating layer 34 contains silicon oxide and the sacrificial layer 24 contains a metal, e.g., tungsten, the ion species is preferably one selected from the group consisting of NFx ion (x>2), SFx ion (x>3), and CFx ion (x>3) containing a large amount of F. The ion energy at this time is preferably lower, for example, 500 eV or less, because it is easy to obtain the selectivity with the insulating layer 34. By irradiating the ion beam containing such ion species, the insulating layer 34 functions as an etching stopper, and the sacrificial layer 24 can be selectively etched. Selectively etching of the sacrificial layer 24 of the stacked body exposes the insulating layer 34.

By subsequently irradiating the region B with the ion beam, the insulating layer 34 of the stacked body exposed by the mask 80 in the region B is selectively etched. To selectively etch the insulating layer 34, the ion beam preferably contains ion species having a higher selectivity for the insulating layer 34 than the sacrificial layer 23. When the insulating layer 34 contains silicon oxide and the sacrificial layer 23 contains silicon nitride, silicon, or tungsten, the ion species is preferably CxFy+ion not containing H. CxFy+ion may be, for example, C₃F₅+ion or C₄F₆+ion. By irradiating the ion beam containing such ion species, the sacrificial layer 23 functions as an etching stopper, and the insulating layer 34 can be selectively etched. Selectively etching of the insulating layer 34 of the stacked body exposes the sacrificial layer 23 to form the contact hole CH3.

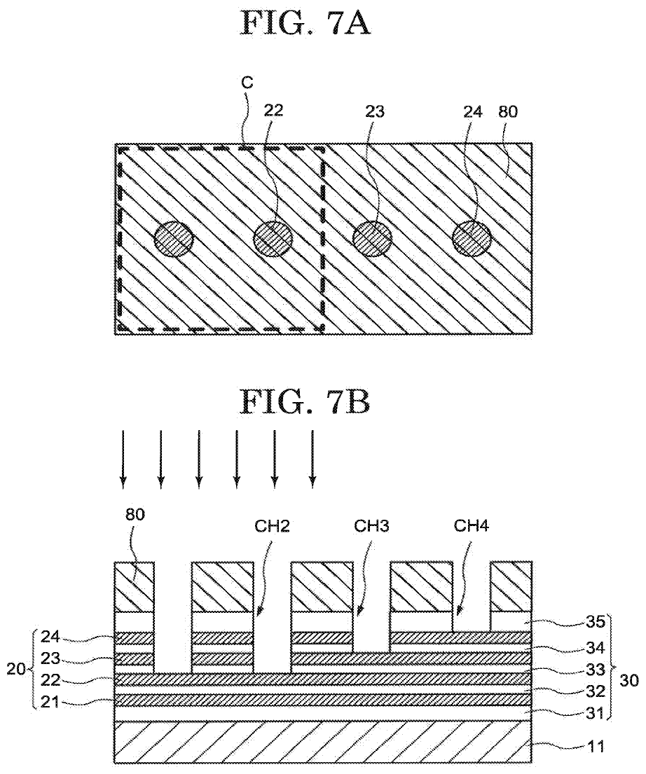

As shown in FIGS. 7A and 7B, by irradiating a region C (third and fourth regions) containing all the regions where the contact holes CH1 and CH2 are formed with the ion beam, the sacrificial layer 23 of the stacked body exposed by the mask 80 in the region C is selectively etched. The region C is a part of the region A and a part of the region B. The region C does not contain the region where the contact holes CH3 and CH4 are formed and may be the smallest region containing all the regions where the contact holes CH1 and CH2 are formed. As described above, to selectively etch the sacrificial layer 23, the ion beam preferably contains ion species having a higher selectivity for the sacrificial layer 23 than the insulating layer 33. When the insulating layer 33 contains silicon oxide and the sacrificial layer 23 contains silicon nitride or silicon, the ion species is preferably CxHyFz+ion containing H. CxHyFz+ion may be, for example, CHF₂+ion or CH₂F+ion. When the insulating layer 33 contains silicon oxide and the sacrificial layer 23 contains a metal, e.g., tungsten, the ion species is preferably one selected from the group consisting of NFx ion (x>2), SFx ion (x>3), and CFx ion (x>3) containing a large amount of F. The ion energy at this time is preferably lower, for example, 500 eV or less, because it is easy to obtain the selectivity with the insulating layer 33. By irradiating the ion beam containing such ion species, the insulating layer 33 functions as an etching stopper, and the sacrificial layer 23 can be selectively etched. Selectively etching of the sacrificial layer 23 of the stacked body exposes the insulating layer 33.

By subsequently irradiating the region C with the ion beam, the insulating layer 33 of the stacked body exposed by the mask 80 in the region C is selectively etched. As described above, to selectively etch the insulating layer 33, the ion beam preferably contains ion species having a higher selectivity for the insulating layer 33 than the sacrificial layer 22. When the insulating layer 33 contains silicon oxide and the sacrificial layer 22 contains silicon nitride, silicon, or tungsten, the ion species is preferably CxFy+ion not containing H. CxFy+ion may be, for example, C₃F₅+ion, or C₄F₆+ion. By irradiating the ion beam containing such ion species, the sacrificial layer 22 functions as an etching stopper, and the insulating layer 33 can be selectively etched. Selectively etching of the insulating layer 33 of the stacked body exposes the sacrificial layer 22 to form the contact hole CH2.

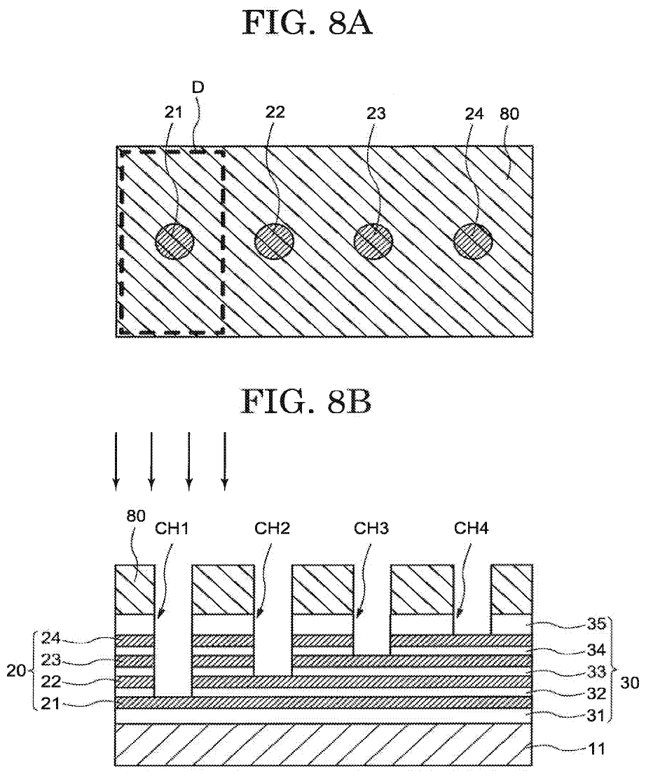

As shown in FIGS. 8A and 8B, by irradiating a region D (fourth region) containing the region where the contact hole CH1 is formed with the ion beam, the sacrificial layer 22 of the stacked body exposed by the mask 80 in the region D is selectively etched. The region D is a part of the region A and a part of the regions B and C. The region D does not contain the region where the contact holes CH2, CH3 and CH4 are formed and may be the smallest region containing the region where the contact hole CH1 is formed. As described above, to selectively etch the sacrificial layer 22, the ion beam preferably contains ion species having a higher selectivity for the sacrificial layer 22 than the insulating layer 32. When the insulating layer 32 contains silicon oxide and the sacrificial layer 22 contains silicon nitride or silicon, the ion species is preferably CxHyFz+ion containing H. CxHyFz+ion may be, for example, CHF₂+ion or CH₂F+ion. When the insulating layer 32 contains silicon oxide and the sacrificial layer 22 contains a metal, e.g., tungsten, the ion species is preferably one selected from the group consisting of NFx ion (x>2), SFx ion (x>3), and CFx ion (x>3) containing a large amount of F. The ion energy at this time is preferably lower, for example, 500 eV or less, because it is easy to obtain the selectivity with the insulating layer 32. By irradiating the ion beam containing such ion species, the insulating layer 32 functions as an etching stopper, and the sacrificial layers 22 can be selectively etched. Selectively etching of the sacrificial layer 22 of the stacked body exposes the insulating layer 32.

By subsequently irradiating the region D with the ion beam, the insulating layer 32 of the stacked body exposed by the mask 80 in the region D is selectively etched. As described above, to selectively etch the insulating layer 32, the ion beam preferably contains ion species having a higher selectivity for the insulating layer 32 than the sacrificial layer 21. When the insulating layer 32 contains silicon oxide and the sacrificial layer 21 contains silicon nitride, silicon, or tungsten, the ion species is preferably CxFy+ion not containing H. CxFy+ion may be, for example, C₃F₅+ion, or C₄F₆+ion. By irradiating the ion beam containing such ion species, the sacrificial layer 21 functions as an etching stopper, and the insulating layer 32 can be selectively etched. Selectively etching of the insulating layer 32 of the stacked body exposes the sacrificial layer 21 to form the contact hole CH1.

In the present embodiment, a method of forming the contact holes CH1, CH2, CH3 and CH4 exposing the four different sacrificial layers 21, 22, 23 and 24 has been described. However, without being limited thereto, and when a larger number of layers are stacked, a larger number of contact holes CH having different depths can be formed by repeating switching and irradiating the ion beam containing a specific ion species for each region that forms the corresponding contact hole.

In the present embodiment, a method of reducing the radiation region in order from the large region A to the small region D is described. However, without being limited thereto, the processes using the regions B, C, and D shown in FIGS. 6A to 8B are not ordered. In the present embodiment, substantially the entire surface of the drawn region HUR is divided for each contact hole CH to form each irradiation region. However, without being limited thereto, the area of the irradiation region can be reduced to about twice area of the contact hole CH. By reducing the irradiation region, the irradiation time of the ion beam can be shortened, and the manufacturing efficiency of the stacked wiring structure can be improved.

As described above, by selectively etching a specific layer by irradiating a specific region with the ion beam containing a specific ion species, the method of manufacturing the stacked wiring structure according to the present embodiment can control the depth of the contact hole CH from the upper surface of the stacked body. As a result, it is possible to improve the reliability of the stacked wiring structure.

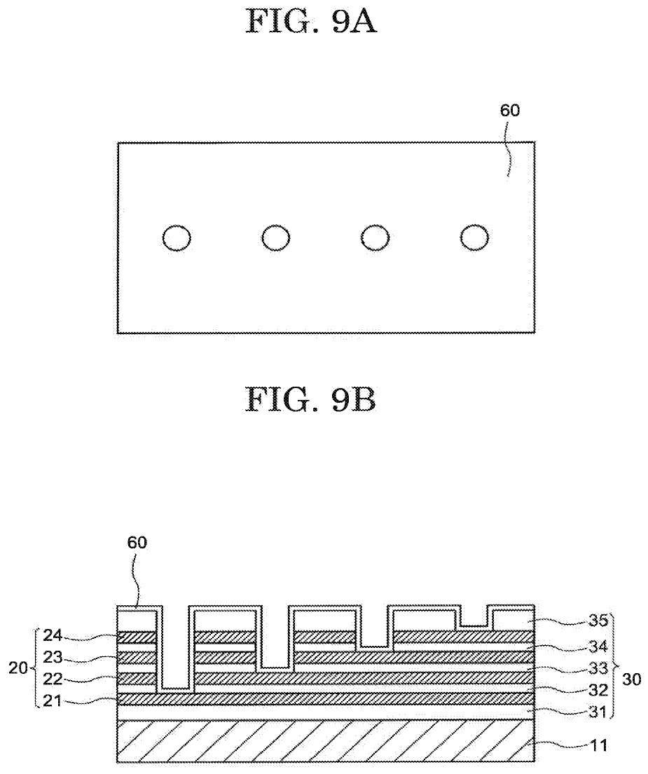

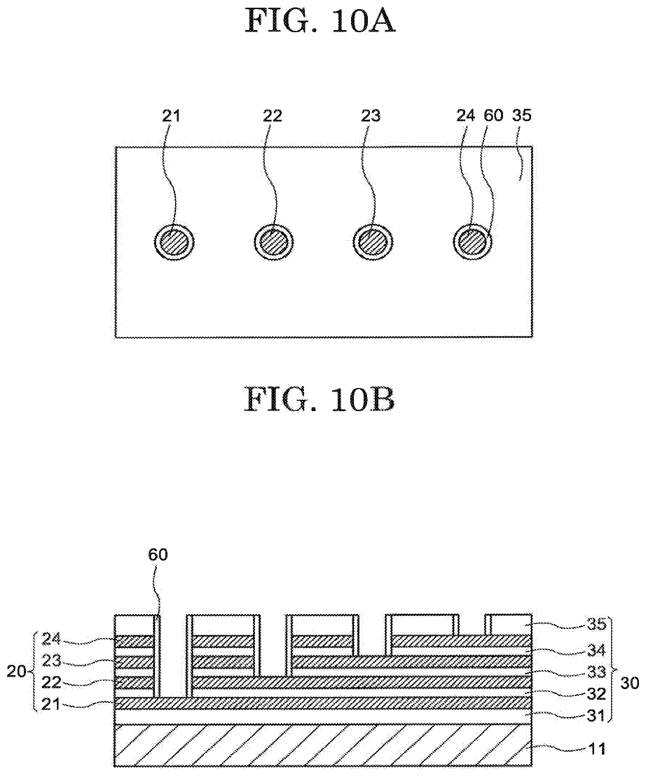

As shown in FIGS. 9A and 9B, after removing the mask 80, the insulating film 60 is formed on the upper surface of the stacked body, the inner side surface and bottom of the contact holes CH. The insulating film 60 may be, for example, silicon oxide and is deposited using the CVD device. The insulating film 60 is also formed on the sacrificial layer 20, which is the bottom of the contact hole CH. Therefore, as shown in FIGS. 10A and 10B, an anisotropic etching such as RIE is performed to remove the insulating film 60 on the upper surface of the stacked body and the bottom of the contact holes. The insulating film 60 remains on the inner side surface of the contact hole CH.

The contact plug 50 is formed by embedding a metal such as tungsten in the contact hole CH that exposes the corresponding sacrificial layer 20 at the bottom. Further, a slit (not shown) is dug down in a predetermined region of the stacked body, and the sacrificial layer 20 contained in the stacked body is collectively removed from the slit. As a result, a cavity is formed in the portion where the sacrificial layer 20 was present. Then, by embedding a metal such as tungsten in the cavity, the conductive layer 70 shown in FIGS. 3A and 3B is formed.

As described above, in the method of manufacturing the stacked wiring structure according to the present embodiment, the contact plug 50 connected to the respective conductive layers in the stacked body can be easily formed by irradiating a specific region with the ion beam containing specific ion species to form the contact holes CH1, CH2, CH3, CH4 having different depths from the upper surface of the stacked body. It is not necessary to use photolithography frequently, and it is possible to improve the manufacturing efficiency of the stacked wiring structure.

### [Configuration of the Ion Beam Irradiation Apparatus]

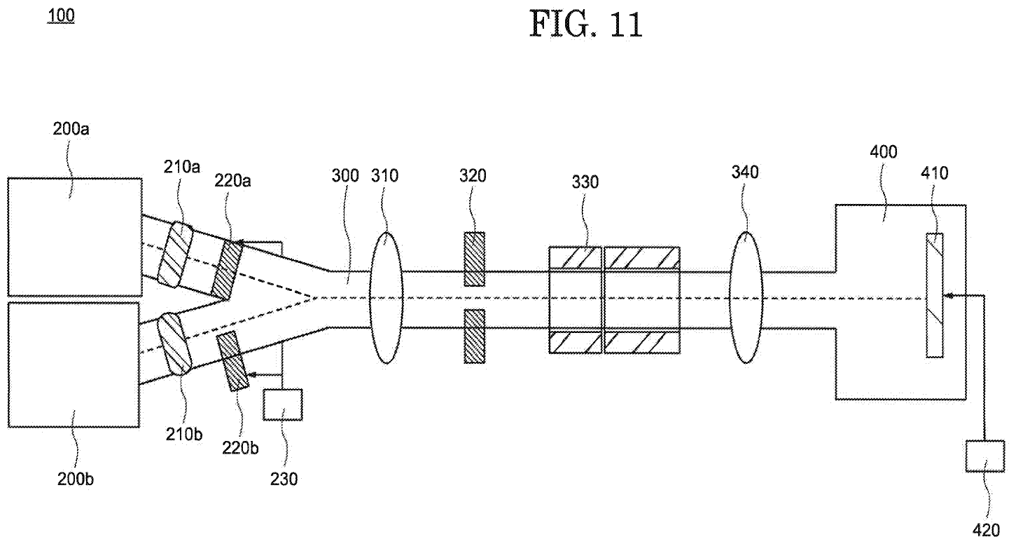

FIG. 11 is a schematic diagram showing a configuration of an ion beam irradiation apparatus. An ion beam irradiation apparatus 100 shown in FIG. 11 is an ECR (Electron Cyclotron Resonance) plasma type, and includes a plasma generation chamber 200, a beam line 300, and a beam irradiation chamber 400.

The plasma generation chamber 200 generates plasma by generating a magnetic field in a vacuum chamber and introducing microwaves. When a gas is introduced in a state where plasma is generated and a predetermined acceleration voltage is applied to an acceleration electrode, the ion beam is generated. The ion beam irradiation apparatus 100 according to the present embodiment includes two plasma generation chambers 200a and 200b configured to generate the ion beam containing different ion species (when not distinguishing the plasma generation chambers 200a and 200b, referred to as the plasma generation chambers 200). The plasma generation chamber 200a may, for example, generate the ion beam containing C₃F₅+ion or C₄F₆+ion for selectively etching the insulating layer 30 (TEOS film) using C₄F₆ gas. The plasma generation chamber 200b may, for example, generate the ion beam containing CHF₂+ion or CH₂F+ion for selectively etching the sacrifice layer 20 (SiN film) using CH₃F gas.

The ion beams generated in the plasma generation chambers 200a and 200b reach one beam line 300 via mass selectors 210a, 210b, and shutters 220a and 220b, respectively. The mass selectors 210a and 210b separate and draw out the respective target ions. For example, after generating CF-based plasma containing a carbon element and a fluorine element or CHF-based plasma containing a carbon element, a hydrogen element, or a fluorine element in the vacuum chamber, C₃F₅+ion, C₄F₆+ion, CHF₂+ion, or CH₂F+ion can be extracted by the mass selectors 210a and 210b. The shutters 220a and 220b are, for example, Faraday cups, and shield the respective ion beams. A shutter control unit 230 controls the opening and closing of the shutters 220a and 220b. The shutter control unit 230 selects one of the two ion beams containing different ion species or shields both of them. That is, the shutter control unit 230 closes the shutter 220b at least when the shutter 220a is opened and closes the shutter 220a when the shutter 220b is opened. By having such a configuration, the two ion beams containing different ion species can be appropriately switched.

The beam line 300 causes the ion beam generated in the plasma generation chamber 200a or the plasma generation chamber 200b to reach the beam irradiation chamber 400 via a condenser lens 310, a diaphragm 320, a deflector 330, and an objective lens 340. The spot size of the ion beam can be controlled by focusing the ion beam with the condenser lens 310, the diaphragm 320, and the objective lens 340. The spot size (full width at half maximum) of the ion beam may be, for example, the nanometer order to the micrometer order. The deflector 330 can scan the ion beam in a fixed order or deflect it to any position.

By having such a configuration, the ion beam can be irradiated only within a specific irradiation region.

The beam irradiation chamber 400 has a stage 410 configured to fix the substrate and a relative position control unit 420 configured to control the relative position of the stage 410 and the ion beam. The relative position control unit 420 can control the irradiation region of the ion beam by moving the stage 410, for example. By having such a configuration, it is possible to control the region to irradiate the ion beam.

As described above, by selectively etching a specific layer by irradiating a specific region with the ion beam containing a specific ion species, the ion beam irradiation apparatus according to the present embodiment can control the depth of the contact hole CH from the upper surface of the stacked body. As a result, it is possible to improve the reliability of the semiconductor device. Further, it is not necessary to use photolithography frequently, and it is possible to improve the manufacturing efficiency of the semiconductor device.

### Second Embodiment

The configuration of the stacked wiring structure according to the present embodiment is the same as the configuration of the stacked wiring structure according to the first embodiment. The method of manufacturing the stacked wiring structure according to the present embodiment is the same as the method of manufacturing the stacked wiring structure according to the first embodiment except for the forming method of the contact holes CH1, CH2, CH3. The same description as that of the first embodiment will be omitted, here will be described portions that are different from the method of manufacturing the stacked wiring structure according to the first embodiment.

### [Method of Manufacturing Stacked Wiring Structure]

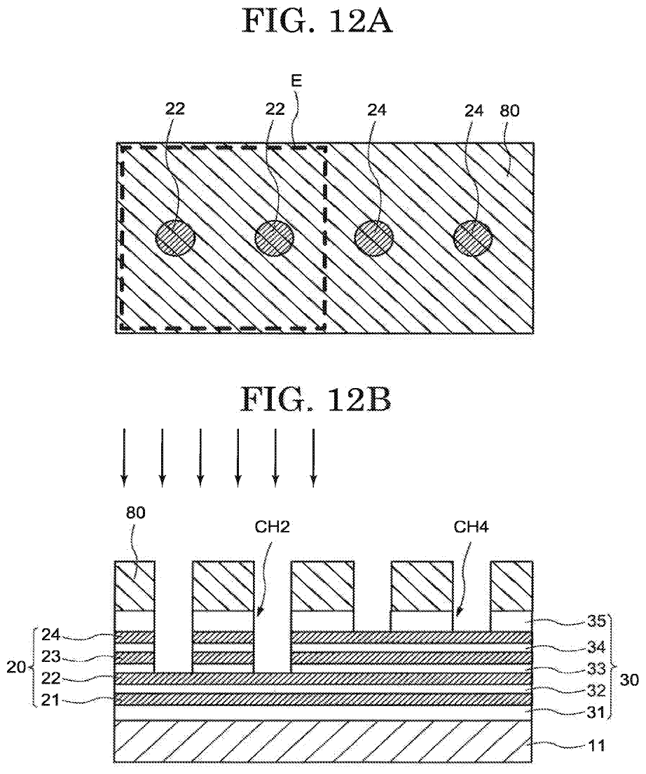

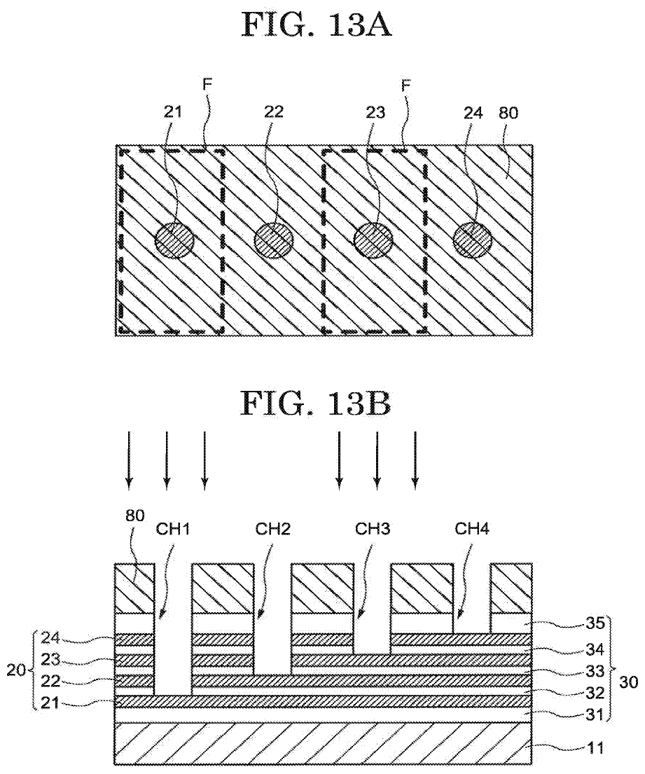

Referring to FIGS. 12A to 13B, a method of manufacturing the stacked wiring structure 17 according to the present embodiment will be described.

First, the contact hole CH4 is formed by the methods described in FIGS. 4A to 5B.

As shown in FIG. 12A and FIG. 12B, by irradiating a region E (third and fourth regions) containing all the regions where the contact holes CH1, CH2 are formed with the ion beam, the sacrificial layer 24 of the stacked body exposed by the mask 80 in the region E is selectively etched. The region E is a part of the region A. The region B does not contain the region where the contact holes CH3, CH4 are formed and may be the smallest region containing the region where the contact holes CH1, CH2 are formed. To selectively etch the sacrificial layer 24, the ion beam preferably contains ion species having a higher selectivity for the sacrificial layer 24 than the insulating layer 34. When the insulating layer 34 contains silicon oxide and the sacrificial layer 24 contains silicon nitride or silicon, the ion species is preferably CxHyFz+ion containing H. CxHyFz+ion may be, for example, CHF₂+ion or CH₂F+ion. When the insulating layer 34 contains silicon oxide and the sacrificial layer 24 contains a metal, e.g., tungsten, the ion species is preferably one selected from the group consisting of NFx ion (x>2), SFx ion (x>3), and CFx ion (x>3) containing a large amount of F. The ion energy at this time is preferably lower, for example, 500 eV or less, because it is easy to obtain the selectivity with the insulating layer 34. By irradiating the ion beam containing such ion species, the insulating layer 34 functions as an etching stopper, and the sacrificial layers 24 can be selectively etched. Selectively etching the sacrificial layer 24 of the stacked body exposes the insulating layer 34.

By subsequently irradiating the region E with the ion beam, the insulating layer 34 of the stacked body exposed by the mask 80 in the region B is selectively etched. To selectively etch the insulating layer 34, the ion beam preferably contains ion species having a higher selectivity for the insulating layer 34 than the sacrificial layer 23. When the insulating layer 34 contains silicon oxide and the sacrificial layer 23 contains silicon nitride, silicon, or tungsten, the ion species is preferably CxFy+ion not containing H. CxFy+ion may be, for example, C₃F₅+ion, or C₄F₆+ion. By irradiating the ion beam containing such ion species, the sacrificial layer 23 functions as an etching stopper, and the insulating layer 34 can be selectively etched. Selectively etching the insulating layer 34 of the stacked body exposes the sacrificial layer 23.

By subsequently irradiating the region E with the ion beam, the sacrificial layer 23 of the stacked body exposed by the mask 80 in the region E is selectively etched. As described above, to selectively etch the sacrificial layer 23, the ion beam preferably contains ion species having a higher selectivity for the sacrificial layer 23 than the insulating layer 33. When the insulating layer 33 contains silicon oxide and the sacrificial layer 23 contains silicon nitride or silicon, the ion species is preferably CxHyFz+ion containing H. CxHyFz+ion may be, for example, CHF₂+ion or CH₂F+ion. When the insulating layer 33 contains silicon oxide and the sacrificial layer 23 contains a metal, e.g., tungsten, the ion species is preferably one selected from the group consisting of NFx ion (x>2), SFx ion (x>3), and CFx ion (x>3) containing a large amount of F. The ion energy at this time is preferably lower, for example, 500 eV or less, because it is easy to obtain the selectivity with the insulating layer 33. By irradiating the ion beam containing such ion species, the insulating layer 33 functions as an etching stopper, and the sacrificial layer 23 can be selectively etched. Selectively etching the sacrificial layer 23 of the stacked body exposes the insulating layer 33.

By subsequently irradiating the region E with the ion beam, the insulating layer 33 of the stacked body exposed by the mask 80 in the region E is selectively etched. As described above, to selectively etch the insulating layer 33, the ion beam preferably contains ion species having a higher selectivity for the insulating layer 33 than the sacrificial layer 22. When the insulating layer 33 contains silicon oxide and the sacrificial layer 22 contains silicon nitride, silicon, or tungsten, the ion species is preferably CxFy+ion not containing H. CxFy+ion may be, for example, C₃F₅+ion, or C₄F₆+ion. By irradiating the ion beam containing such ion species, the sacrificial layer 22 functions as an etching stopper, and the insulating layer 33 can be selectively etched. Selectively etching the insulating layer 33 of the stacked body exposes the sacrificial layer 22 to form the contact hole CH2.

As shown in FIGS. 13A and 13B, by irradiating a region F (second and fourth regions) containing the region where the contact holes CH1, CH3 are formed with the ion beam, the sacrificial layer 22 and the sacrificial layer 24 of the stacked body exposed by the mask 80 in the region F are selectively etched. The region F is a part of the region A. The region F does not contain the region where the contact holes CH2, CH4 are formed and may be the smallest region containing the region where the contact holes CH1, CH3 are formed. As described above, to selectively etch the sacrificial layer 22 and the sacrificial layer 24, the ion beam preferably contains ion species having a higher selectivity for the sacrificial layer 22 and the sacrificial layer 24 than the insulating layer 32 and the insulating layer 34. When the insulating layer 32 and the insulating layer 34 contain silicon oxide and sacrificial layer 22 and sacrificial layer 24 contain silicon nitride or silicon, the ion species is preferably CxHyFz+ion containing H. CxHyFz+ion may be, for example, CHF₂+ion or CH₂F+ion. When the insulating layer 32 and the insulating layer 34 contain silicon oxide and the sacrificial layer 22 and the sacrificial layer 24 contain a metal, e.g., tungsten, the ion species is preferably one selected from the group consisting of NFx ion (x>2), SFx ion (x>3), CFx ion (x>3) containing a large amount of F. The ion energy at this time is preferably lower, for example, 500 eV or less, because it is easy to obtain the selectivity with the insulating layer 32 and the insulating layer 34. By irradiating the ion beam containing such ion species, the insulating layer 32 and the insulating layer 34 function as the etching stoppers, and the sacrificial layer 22 and the sacrificial layer 24 can be selectively etched. Selectively etching the sacrificial layer 22 and the sacrificial layer 24 of the stacked body exposes the insulating layer 32 and the insulating layer 34.

By subsequently irradiating the region F with the ion beam, the insulating layer 32 and the insulating layer 34 of the stacked body exposed by the mask 80 in the region F are selectively etched. As described above, to selectively etch the insulating layer 32 and the insulating layer 34, the ion beam preferably contains ion species having a higher selectivity for the insulating layer 32 and the insulating layer 34 than the sacrificial layer 21 and the sacrificial layer 23. When the insulating layer 32 and the insulating layer 34 contain silicon oxide and the sacrificial layer 21 and the sacrificial layer 23 contain silicon nitride, silicon, or tungsten, the ion species is preferably CxFy+ion not containing H. CxFy+ion may be, for example, C3F5+ion, or C4F6+ion. By irradiating the ion beam containing such ion species, the sacrificial layer 21 and the sacrificial layer 23 function as the etching stoppers, and the insulating layer 32 and the insulating layer 34 can be selectively etched. Selectively etching the insulating layer 32 and the insulating layer 34 of the stacked body exposes the sacrificial layer 21 and the sacrificial layer 23 to form the contact holes CH1 and CH3.

In the present embodiment, a method of forming the contact holes CH1, CH2, CH3, CH4 exposing the four different sacrificial layers 21, 22, 23, 24 has been described. However, without being limited thereto, and when a larger number of layers are stacked, a larger number of contact holes CH having different depths can be formed by repeating switching and irradiating the ion beam containing a specific ion species for each region that forms the corresponding contact hole. The processes using the regions E and F shown in FIGS. 12A to 13B are not ordered. Switching of the irradiation region is less once than the method of manufacturing the stacked wiring structure according to the first embodiment, and the same stacked wiring structure can be manufactured.

The stacked wiring structure 17 shown in FIG. 3A and FIG. 3B is formed by manufacturing the stacked wiring structure by the methods described in FIGS. 9A to 10B.

As described above, by selectively etching a specific layer by irradiating a specific region with the ion beam containing a specific ion species, the method of manufacturing the stacked wiring structure according to the present embodiment can control the depth of the contact hole CH from the upper surface of the stacked body. As a result, it is possible to improve the reliability of the stacked wiring structure. Further, as the contact plug 50 connected to the respective conductive layers in the stacked body can easily be formed, it is possible to improve the manufacturing efficiency of the stacked wiring structure.

### Third Embodiment

The configuration of the stacked wiring structure according to the present embodiment is the same as the configuration of the stacked wiring structure according to the first embodiment except for the shape of the contact hole CH and the contact plug 50. The method of manufacturing the stacked wiring structure according to the present embodiment is the same as the method of manufacturing the stacked wiring structure according to the first embodiment except that the ion beam is irradiated only to the region where the contact hole CH is formed without using the mask 80. Descriptions that are the same as those of the first embodiment will be omitted, and here, portions that are different from the configuration and the method of manufacturing the stacked wiring structure according to the first embodiment will be described.

### [Configuration of the Stacked Wiring Structure]

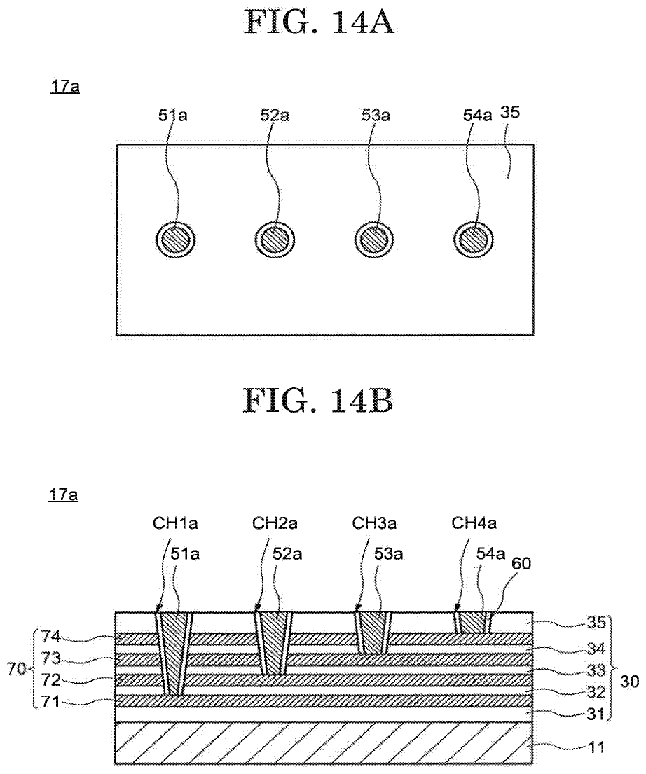

FIG. 14A is a top view showing the configuration of a stacked wiring structure 17a. FIG. 14B is a cross-sectional view showing the configuration of the stacked wiring structure 17a. The stacked wiring structure 17a has the plurality of conductive layers 71, 72, 73, and 74 stacked on the semiconductor substrate 11. The plurality of conductive layers 71, 72, 73, and 74, and the plurality of insulating layers 31, 32, 33, 34, and 35 are alternately periodically stacked in a direction perpendicular to the main surface of the semiconductor substrate 11.

Contact holes CH1a, CH2a, CH3a, and CH4a (when not distinguishing the contact holes CH1a, CH2a, CH3a, and CH4a, referred to as the contact holes CHa) are formed up to the corresponding conductive layers 71, 72, 73, and 74 by penetrating the plurality of conductive layers 70 and the plurality of insulating layers 30, which are the upper layer and stacked with each other. That is, the depth of each of the contact holes CH1a, CH2a, CH3a, and CH4a from the upper surface of the stacked wiring structure 17a is different. In the present embodiment, the contact hole CHa has different diameters at the top surrounded by the insulating layer 35 and at the bottom connected to the corresponding conductive layer. The contact hole CHa has a smaller diameter at the bottom than at the top. However, without being limited thereto, the diameter at the intermediate portion between the top and bottom may be larger than the diameter at the top.

A contact plug 50a is formed in the contact hole CHa. The length of the contact plugs 51a, 52a, 53a, and 54a from the upper surface of the stacked wiring structure 17a is different, respectively. Each of the contact plugs 50a may have a frusto-conical shape.

The contact plug 50a is insulated from the upper conductive layer 70 penetrating by the contact hole CHa. The insulating film 60 is formed in a cylindrical shape on the side surface of the contact hole CHa. That is, the side surface of the contact plug 50a is covered with the insulating film 60.

### [Method of Manufacturing Stacked Wiring Structure]

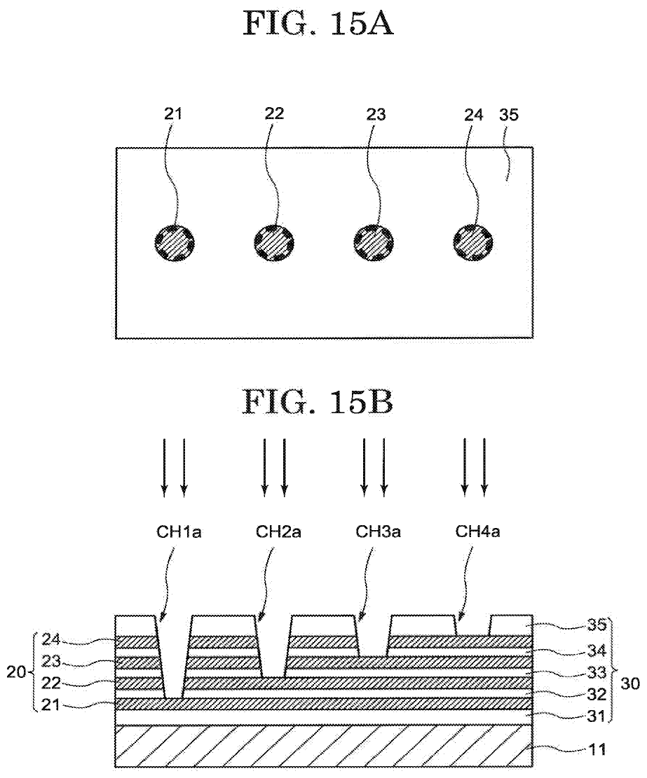

Referring to FIGS. 15A and 15B, a method of manufacturing the stacked wiring structure 17a according to the present embodiment will be described.

In the present embodiment, the mask does not have to be formed. The contact hole CHa is formed by etching by irradiating the region forming each contact hole CHa with the ion beam. It is same as the method of manufacturing the stacked wiring structure according to the first embodiment and the second embodiment, except that the region to be irradiated with the ion beam is limited to the region forming the contact hole CHa, and thus the description thereof will be omitted. Compared to the method of manufacturing the stacked wiring structure according to the first embodiment, a similar stacked wiring structure can be manufactured without the need to form a mask.

As described above, by selectively etching a specific layer by irradiating a specific region with the ion beam containing a specific ion species, the method of manufacturing the stacked wiring structure according to the present embodiment can control the depth of the contact hole CHa from the upper surface of the stacked body. As a result, it is possible to improve the reliability of the stacked wiring structure. Further, as the contact plug 50a connected to the respective conductive layers in the stacked body can easily be formed, it is possible to improve the manufacturing efficiency of the stacked wiring structure.

### Fourth Embodiment

The configuration of the stacked wiring structure according to the present embodiment is the same as the configuration of the stacked wiring structure according to the first embodiment, except that the stacked body is a staircase structure. The method of manufacturing the stacked wiring structure according to the present embodiment is the same as the method of manufacturing the stacked wiring structure according to the first embodiment, except that the staircase structure of the stacked body is formed using the ion beam without using the mask 80. Descriptions that are the same as those of the first embodiment will be omitted, and here, portions that are different from the configuration and the method of manufacturing the stacked wiring structure according to the first embodiment will be described.

### [Configuration of Stacked Wiring Structure]

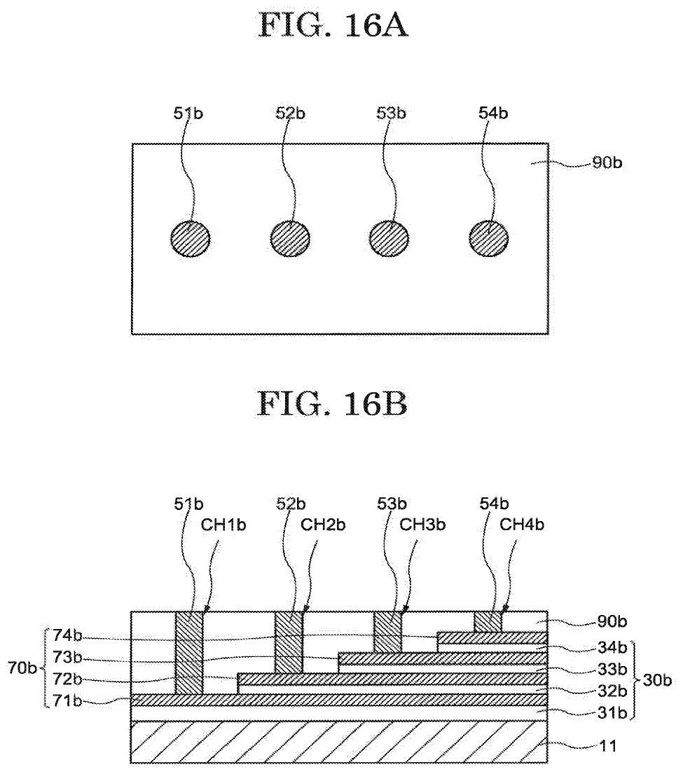

FIG. 16A is a top view showing a configuration of a stacked wiring structure 17b. FIG. 16B is a cross-sectional view showing the configuration of the stacked wiring structure 17b. The stacked wiring structure 17b has a plurality of conductive layers 71 b, 72b, 73b, and 74b stacked on the semiconductor substrate 11. The plurality of conductive layers 71b, 72b, 73b, and 74b, and a plurality of insulating layers 31b, 32b, 33b, 34b, and 35b are alternately periodically stacked in a direction perpendicular to the main surface of the semiconductor substrate 11. The plurality of conductive layers 71b, 72b, 73b, and 74b and the plurality of insulating layers 31b, 32b, 33b, 34b, and 35b are formed in a staircase structure, respectively, to expose the lower conductive layer 70b. An insulator 90b to embed the staircase structure is formed on the stacked body.

In the insulator 90b, contact holes CH1b, CH2b, CH3b, and CH4b (when not distinguishing the contact holes CH1b, CH2b, CH3b, and CH4b, referred to as the contact holes CHb) are formed. The contact holes CH1b, CH2b, CH3b, and CH4b are formed up to the corresponding conductive layers 71b, 72b, 73b, and 74b by penetrating the insulator 90b. That is, the depth of each the contact holes CH1b, CH2b, CH3b, and CH4b from the upper surface of the stacked wiring layer structure 17b is different. In the present embodiment, the contact hole CHb has substantially the same diameter at the top surrounded by the insulator 90b and at the bottom connected to the corresponding conductive layer. However, without being limited thereto, the contact hole CHb may have different diameters at the top and bottom or may have a larger diameter at the intermediate portion between the top and bottom than at the top or bottom.

Contact plugs 51b, 52b, 53b, and 54b are formed in the contact hole CHb. The length of the contact plugs 51 b, 52b, 53b, and 54b from the upper surface of the stacked wiring structure 17b is different, respectively.

### [Method of Manufacturing Stacked Wiring Structure]

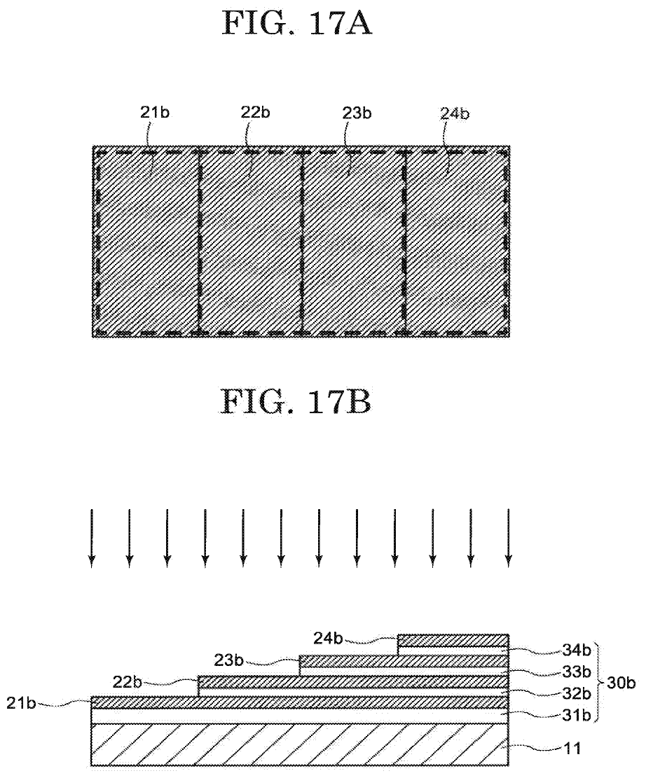

Referring to FIGS. 17A and 17B, a method of manufacturing the stacked wiring structure 17b according to the present embodiment will be described.

In the present embodiment, a mask is not formed. The staircase structure of the stacked body according to the present embodiment is formed by etching by irradiating the ion beam as described in the method of manufacturing the stacked wiring structure according to the first embodiment without using a mask. It is same as the method of manufacturing the stacked wiring structure according to the first embodiment and the second embodiment, except that a mask is not used when irradiating the ion beam, and thus the description thereof will be omitted. Compared to the method of manufacturing the stacked wiring structure according to the first embodiment, a similar stacked wiring structure can be manufactured without the need to form a mask.

As described above, by selectively etching a specific layer by irradiating a specific region with the ion beam containing a specific ion species, the method of manufacturing the stacked wiring structure according to the present embodiment can control the steps of the staircase structure. As a result, it is possible to improve the reliability of the stacked wiring structure. Further, the contact plug 50b connected to the respective conductive layers in the stacked body can easily be formed, it is possible to improve the manufacturing efficiency of the stacked wiring structure.

### Fifth Embodiment

The configuration of the stacked wiring structure according to the present embodiment is the same as the configuration of the stacked wiring structure according to the first embodiment. The method of manufacturing the stacked wiring structure according to the present embodiment is the same as the method of manufacturing the stacked wiring structure according to the first embodiment. The configuration of the ion beam irradiation apparatus according to the present embodiment is the same as the configuration of the ion beam irradiation apparatus according to the first embodiment, except that the ion beam irradiation apparatus according to the present embodiment has the two beam lines. Descriptions that are the same as those of the first embodiment are omitted, and portions different from the configuration of the ion beam irradiation apparatus according to the first embodiment will be described.

### [Configuration of Ion Beam Irradiation Apparatus]

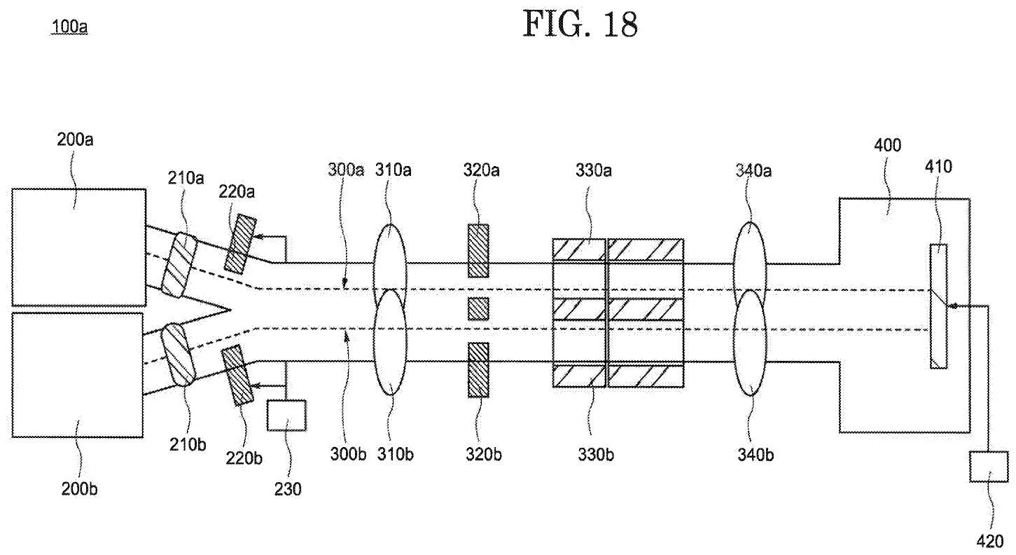

FIG. 18 is a schematic diagram showing a configuration of an ion beam irradiation apparatus. An ion beam irradiation apparatus 100a shown in FIG. 18 is the ECR (Electron Cyclotron Resonance) plasma type, and includes the plasma generation chamber 200, the beam line 300, and the beam irradiation chamber 400.

The ion beam irradiation apparatus 100a according to the present embodiment includes the two plasma generation chambers 200a and 200b configured to generate the ion beam containing the same ion species (when not distinguishing the plasma generation chambers 200a and 200b, referred to as the plasma generation chambers 200). The plasma generation chambers 200a and 200b may generate the ion beam containing, for example, both of C₃F₅+ion or C₄F₆+ion for selectively etching the insulating layer 30 (TEOS film), and CHF₂+ion or CH₂F+ion for selectively etching the sacrificial layer 20 (SiN film).

The ion beams generated in the plasma generation chambers 200a and 200b reach beam lines 300a and 300b, respectively, via the mass selectors 210a and 210b and the shutters 220a and 220b, respectively. The mass selectors 210a and 210b separate and draw out the respective target ions. For example, after generating both CF-based plasma containing a carbon element and a fluorine element and CHF-based plasma containing a carbon element, a hydrogen element, and a fluorine element in the vacuum chamber, either C₃F₅+ion, C₄F₆+ion, or CHF₂+ion or CH₂F+ion can be extracted (selected) by the mass selectors 210a and 210b. The mass selectors 210a and 210b extract (select) the same ion species. The shutters 220a and 220b are, for example, Faraday cups, and shield the respective ion beams. The shutter control unit 230 controls the opening and closing of the shutters 220a and 220b. The shutter control unit 230 irradiates the two ion beams containing the same ion species or shields both of them. That is, the shutter control unit 230 opens the shutter 220b at least when the shutter 220a is opened and closes the shutter 220b when the shutter 220a is closed. By having such a configuration, the two ion beams containing the same ion species can be irradiated simultaneously, and the etching efficiency can be improved.

The beam lines 300a and 300b cause the ion beam generated in the plasma generation chamber 200a or 200b to reach the beam irradiation chamber 400 via condenser lenses 310a and 310b, diaphragms 320a and 320b, deflectors 330a and 330b, and objective lenses 340a and 340b. The ion beam can control the spot size of the ion beam by focusing the ion beam with the condenser lenses 310a and 310b, the diaphragms 320a and 320b, and the objective lenses 340a and 340b. The spot size (full width at half maximum) of the ion beam may be, for example, the nanometer order to the micrometer order. The deflectors 330a and 330b can scan the ion beam in a fixed order or deflect it to any position. By having such a configuration, the two ion beams can be irradiated only within a specific irradiation region.

The beam irradiation chamber 400 has the stage 410 configured to fix the substrate and the relative position control unit 420 configured to control the relative position of the stage 410 and the ion beam. The relative position control unit 420 can control the irradiation region of the ion beam by moving the stage 410, for example. By having such a configuration, it is possible to control the region to irradiate the two ion beams.

As described above, by selectively etching a specific layer by irradiating a specific region with the ion beam containing a specific ion species, the ion beam irradiation apparatus according to the present embodiment can control the depth of the contact hole CH from the upper surface of stacked body. As a result, it is possible to improve the reliability of the semiconductor device. Further, it is not necessary to use photolithography frequently, and it is possible to improve the manufacturing efficiency of the semiconductor device.

### MODIFIED EXAMPLE 1

The configuration of the ion beam irradiation apparatus according to the present modified example is the same as the configuration of the ion beam irradiation apparatus according to the fifth embodiment, except that different ion species are selected by the two mass selectors. Descriptions that are the same as those of the fifth embodiment are omitted, and portions different from the configuration of the ion beam irradiation apparatus according to the fifth embodiment will be described.

### [Configuration of Ion Beam Irradiation Apparatus]

The ion beam irradiation apparatus 100a according to the present modified example includes the two plasma generation chambers 200a and 200b configured to generate the ion beam containing the same ion species (when not distinguishing the plasma generation chambers 200a and 200b, referred to as the plasma generation chambers 200). The plasma generation chambers 200a and 200b may generate the ion beam containing, for example, both of C₃F₅+ion or C₄F₆+ion for selectively etching the insulating layer 30 (TEOS film), and CHF₂+ion or CH₂F+ion for selectively etching the sacrificial layer 20 (SiN film).

The ion beams generated in the plasma generation chambers 200a and 200b reach the beam lines 300a and 300b, respectively, via the mass selectors 210a and 210b and the shutters 220a and 220b, respectively. The mass selectors 210a and 210b separate and draw out the respective target ions. For example, after generating both CF-based plasma containing a carbon element and a fluorine element and CHF-based plasma containing a carbon element, a hydrogen element, and a fluorine element in the vacuum chamber, either C₃F₅+ion, C₄F₆+ion, or CHF₂+ion or CH₂F+ion can be extracted (selected) by the mass selectors 210a and 210b. The mass selectors 210a and 210b extract (select) different ion species. The shutters 220a and 220b are, for example, Faraday cups, and shield the respective ion beams. The shutter control unit 230 controls the opening and closing of the shutters 220a and 220b. The shutter control unit 230 selects one of the two ion beams containing different ion species or shields both of them. That is, the shutter control unit 230 closes the shutter 220b at least when the shutter 220a is opened and closes the shutter 220a when the shutter 220b is opened. By having such a configuration, the two ion beams containing different ion species can be appropriately switched.

As described above, by selectively etching a specific layer by irradiating a specific region with the ion beam containing a specific ion species, the ion beam irradiation apparatus according to the present modified example can control the depth of the contact hole CH from the upper surface of the stacked body. As a result, it is possible to improve the reliability of the semiconductor device. Further, it is not necessary to use photolithography frequently, and it is possible to improve the manufacturing efficiency of the semiconductor device.

### MODIFIED EXAMPLE 2

The configuration of the ion beam irradiation apparatus according to the present modified example is the same as that of the ion beam irradiation apparatus according to the fifth embodiment, except that the ion beam irradiation apparatus according to the present modified example has one plasma generation chamber, one beam line, and one beam irradiation chamber. Descriptions that are the same as those of the fifth embodiment are omitted, and portions different from the configuration of the ion beam irradiation apparatus according to the fifth embodiment will be described.

### [Configuration of Ion Beam Irradiation Apparatus]

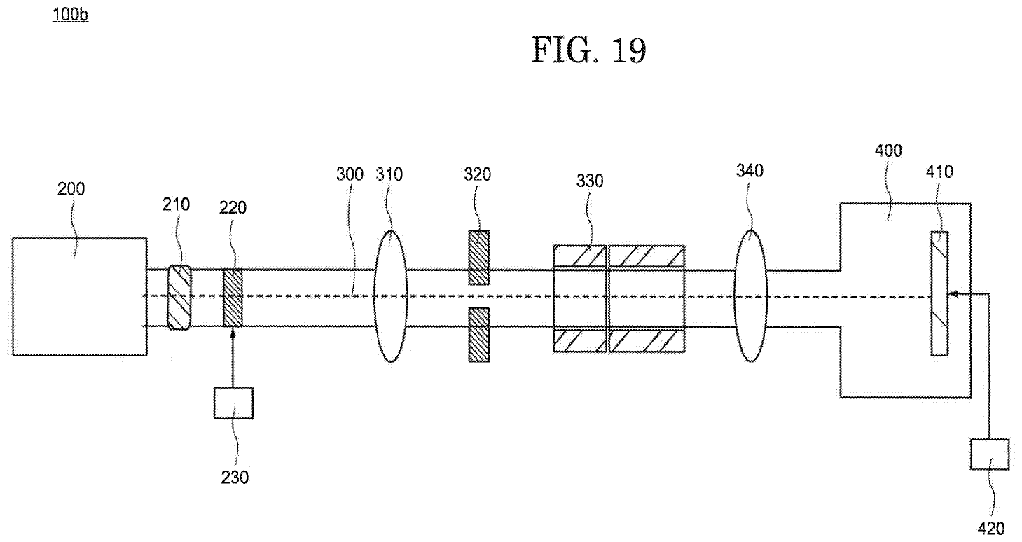

FIG. 19 is a schematic diagram showing a configuration of the ion beam irradiation apparatus. An ion beam irradiation apparatus 100b shown in FIG. 19 is the ECR (Electron Cyclotron Resonance) plasma type and includes the plasma generation chamber 200, the beam line 300, and the beam irradiation chamber 400.

The ion beam irradiation apparatus 100b according to the present modified example includes one plasma generation chamber 200. The plasma generation chamber 200 may generate the ion beam containing, for example, C₃F₅+ion or C₄F₆+ion for selectively etching the insulating layer 30 (TEOS film), and CHF₂+ion or both CH₂F+ion for selectively etching the sacrifice layer 20 (SiN film).

The ion beam generated in the plasma generation chamber 200 reaches one beam line 300 via a mass selector 210, a shutter 220. The mass selector 210 separates and draw outs the target ion. For example, after generating both CF-based plasma containing a carbon element and a fluorine element and CHF-based plasma containing a carbon element, a hydrogen element, and a fluorine element in the vacuum chamber, either C₃F₅+ion or C₄F₆+ion, or CHF₂+ion or CH₂F+ion can be extracted by the mass selector 210. The shutter 220 is, for example, a

Faraday cup, and shields the ion beam. The shutter control unit 230 controls the opening and closing of the shutter 220. By having such a configuration, the ion beam containing two different ion species can be appropriately switched.

As described above, by selectively etching a specific layer by irradiating a specific region with the ion beam containing a specific ion species, the ion beam irradiation apparatus according to the present modified example can control the depth of the contact hole CH from the upper surface of the stacked body. As a result, it is possible to improve the reliability of the semiconductor device. Further, it is not necessary to use photolithography frequently, and it is possible to improve the manufacturing efficiency of the semiconductor device.

While the present invention has been described with reference to the drawings, the present invention is not limited to the above embodiments and can be appropriately modified without departing from the spirit of the present invention. For example, a skilled in the art who adds, deletes, or changes designs of components as appropriate based on the semiconductor device of the present embodiment is also included in the scope of the present invention as long as the gist of the present invention is provided. Furthermore, the embodiments described above can be appropriately combined as long as there is no mutual inconsistency, and technical matters common to the embodiments are included in the embodiments even if they are not explicitly described.

Even if it is other working effects that are different from the working effect brought about by the mode of each above-mentioned embodiment, what is clear from the description in this description, or what can be easily predicted by the person skilled in the art is naturally understood to be brought about by the present invention.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method of manufacturing a semiconductor device comprising:
preparing a stacked body in which a first layer, a second layer, a third layer, and a fourth layer are stacked in this order on a semiconductor substrate in a first direction, the stacked body including a first region and a second region different from the first region;
etching the fourth layer in the first region and the second region to expose the third layer by irradiating the first region and the second region with an ion beam; and
etching the third layer and the second layer in the second region to expose the first layer by irradiating the second regions with an ion beam in a state where the third layer is exposed in the first region.

2. The method of manufacturing a semiconductor device according to claim 1, wherein;
etching the fourth layer includes irradiating the ion beam containing a first ion species having a higher selectivity for the fourth layer than the third layer,
etching the third layer includes irradiating the ion beam containing a second ion species having a higher selectivity for the third layer than the second layer, and
etching the second layer includes irradiating the ion beam containing the first ion species having a higher selectivity for the second layer than the first layer.

3. The method of manufacturing a semiconductor device according to claim 2, wherein;
the second layer and the fourth layer contain silicon oxide,
the first ion species contains CxFy+ion,
the first layer and the third layer contain silicon nitride or silicon, and
the second ion species contains CxHyFz+ion.

4. The method of manufacturing a semiconductor device according to claim 2, wherein;
the second layer and the fourth layer contain silicon oxide,
the first ion species contains CxFy+ion,
the first layer and the third layer contain a metal, and
the second ion species contains one selected from the group consisting of NFx ion (x>2), SFx ion (x>3), and CFx ion (x>3).

5. The method of manufacturing a semiconductor device according to claim 2, wherein;
the ion beam containing the first ion species and the ion beam containing the second ion species are generated in different plasma generation chambers, and the ion species are selected using respective shutters.

6. The method of manufacturing a semiconductor device according to claim 2, wherein;
the ion beam containing the first ion species and the ion beam containing the second ion species are generated in one plasma generation chamber, and the ion species are selected using a mass selector.

7. The method of manufacturing a semiconductor device according to claim 6, wherein;
the plasma generation chamber includes a plurality of plasma generation chambers, and a plurality of ion beams are simultaneously irradiated.

8. The method of manufacturing a semiconductor device according to claim 1, wherein;
preparing a stacked body further comprises forming a mask having openings in the first region and the second region on the fourth layer.

9. The method of manufacturing a semiconductor device according to claim 8, wherein;
a material of the mask contains carbon.

10. The method of manufacturing a semiconductor device according to claim 1, further comprising:
forming an insulating film in a stacking direction of the second region.

11. The method of manufacturing a semiconductor device according to claim 1, further comprising:
forming a conductor in the second region.

12. The method of manufacturing a semiconductor device according to claim 1, further comprising:
removing the first layer and the third layer to form a conductive layer when the first layer and the third layer contain silicon nitride or silicon.

13. A method of manufacturing a stacked wiring structure comprising:
preparing a stacked body in which a first layer, a second layer, a third layer, and a fourth layer are stacked in this order in a first direction, the stacked body including a first region and a second region different from the first region;
etching the fourth layer in the first region and the second region to expose the third layer by irradiating the first region and the second region with an ion beam; and
etching the third layer and the second layer in the second region to expose the first layer by irradiating the second regions with an ion beam in a state where the third layer is exposed in the first region.

14. An Ion beam irradiation apparatus comprising:
a first plasma generation chamber configured to generate a first ion beam;
a first shutter configured to shield the first ion beam;
a shutter control unit configured to control the opening and closing of the first shutter; and
a beam irradiation chamber including a stage configured to for fixing the substrate and a relative position control unit control unit configured to control the relative position of the stage and the first ion beam.

15. The Ion beam irradiation apparatus according to claim 14, further comprising:
a second plasma generation chamber configured to generate a second ion beam; and
a second shutter configured to shield the second ion beam;
wherein the shutter control unit also controls the opening and closing of the second shutter.

16. The Ion beam irradiation apparatus according to claim 15, wherein;
the first plasma generation chamber generates an ion beam containing a first ion species,
the second plasma generation chamber generates an ion beam containing a second ion species different from the first ion species, and
the shutter control unit closes the second shutter when the first shutter is opened, and the shutter control unit closes the first shutter when the second shutter is opened.

17. The Ion beam irradiation apparatus according to claim 14, wherein;
the first plasma generation chamber generates an ion beam containing a first ion species and an ion beam containing a second ion species different from the first ion species,
the first plasma generation chamber includes a first mass selector that selects the first ion species or the second ion species, and
the first plasma generation chamber generates the first ion beam containing the ion species selected by the first mass selector.

18. The Ion beam irradiation apparatus according to claim 15, wherein;
the first plasma generation chamber generates an ion beam containing a first ion species and an ion beam containing a second ion species different from the first ion species,
the first plasma generation chamber includes a first mass selector that selects the first ion species or the second ion species,
the first plasma generation chamber generates the first ion beam containing the ion species selected by the first mass selector,
the second plasma generation chamber generates the ion beam containing the first ion species and the ion beam containing the second ion species,
the second plasma generation chamber includes a second mass selector that selects the first ion species or the second ion species, and
the second plasma generation chamber generates the second ion beam containing the ion species selected by the second mass selector.

19. The Ion beam irradiation apparatus according to claim 18, wherein;
the first ion beam and the second ion beam contain the same ion species,
the shutter control unit opens the second shutter when the first shutter is opened, and the shutter control unit closes the second shutter when the first shutter is closed.

20. The Ion beam irradiation apparatus according to claim 18, wherein;
the first ion beam and the second ion beam contain different ion species,
the shutter control unit closes the second shutter when the first shutter is opened, and the shutter control unit closes the first shutter when the second shutter is opened.
